(19) United States
(12) Patent Application Publication
(10) Pub. No.: US 2014/0254104 A1
(43) Pub. Date: Sep. 11, 2014

(54) HEAT DISSIPATING MODULE

(71) Applicant: Delta Electronics, Inc., Taoyuan Hsien (TW)

(72) Inventors: Hung-Chuan CHEN, Taoyuan Hsien (TW); Cheng-Wei HSU, Taoyuan Hsien (TW)

(73) Assignee: Delta Electronics, Inc., Taoyuan Hsien (TW)

(21) Appl. No.: 14/010,119

(22) Filed: Aug. 26, 2013

(30) Foreign Application Priority Data
Mar. 7, 2013 (TW) 102108130

(51) Int. Cl. H05K 7/20

(52) U.S. Cl. CPC H05K 7/20
USPC 361/720

(57) ABSTRACT

A heat dissipating module comprises at least one substrate and a heat dissipating layer. The substrate has a first surface and a second surface. The heat dissipating layer is disposed on the second surface. At least one heat generating device is electrically connected to the first surface, and the heat dissipating module is disposed on a main board uprightly. The heat dissipating module is advantageous for shortening the manufacturing time, raising the efficiency of automated production, decreasing the assembling cost and further achieving high heat dissipating efficiency.

### CROSS REFERENCE TO RELATED APPLICATIONS

This Non-provisional application claims priority under 35 U.S.C. §119(a) on Patent Application No(s). 102108130 filed in Taiwan, Republic of China on Mar. 7, 2013, the entire contents of which are hereby incorporated by reference.

### BACKGROUND OF THE INVENTION

1. Field of Invention

The invention relates to a heat dissipating module and, in particular, to a heat dissipating module that is compacted and is improved in heat dissipating efficiency.

2. Related Art

With the progress of electronic industry, the electronic devices are demanded with higher operational speed and efficiency, but the accompanying heat dissipation also becomes a serious problem. If the heat dissipation is not solved appropriately, the operational performance and stability will be lowered down, and even the electronic apparatus is damaged or becomes worse in efficiency. In order to make the electronic apparatus operate normally, a heat dissipating device is often installed on the electronic device that will generates heat during the operation, for dissipating the generated heat.

Besides, due to the improved technology, the electronic apparatus is compacted more and more for portability, and the micro-electronic device therein is also reduced in size. Therefore, the accumulated heat in a unit area in the electronic apparatus is increased, and thus the heat dissipating apparatus capable of high heat dissipating efficiency is really required. Moreover, because the micro-electronic device has a smaller size, a large-type heat dissipating device is unsuitable for being disposed thereon. Besides, the heat dissipating device also occupies some room of the electronic apparatus.

In the conventional art, a heat dissipating sheet is used as the main heat dissipating device, disposed on the power component of a mother board or circuit board for the heat dissipation. However, disposing the heat dissipating device to the motherboard having complex power components or to the circuit board having a complex circuit not only increases the manufacturing time but also provides limited heat dissipation effect. Furthermore, in a system having more components or complex structure, the disposition space and heat dissipation effect must be considered together, so the design of the heat dissipating device and entire configuration must become more complicated, and therefore the manufacturing time and cost are definitely increased. Moreover, a conventional heat generating device and heat dissipating device are connected to each other mainly by screwing, and such connection way will increase the manufacturing time and is unfavorable for automation.

Therefore, it is an important subject to provide a heat dissipating module that can be improved in heat dissipating efficiency, and can decrease the production time and cost just through a simple design and configuration.

### SUMMARY OF THE INVENTION

In view of the foregoing subject, an objective of this invention is to provide a heat dissipating module that can be improved in heat dissipating efficiency, and can decrease the production time and cost just through a simple design and configuration.

To achieve the above objective, a heat dissipating module according to the invention comprises at least one substrate and a heat dissipating layer. The substrate has a first surface and a second surface. The heat dissipating layer is disposed on the second surface. At least one heat generating device is electrically connected to the first surface, and the heat dissipating module is disposed on a main board uprightly.

In one embodiment, the heat dissipating module further comprises at least one wire disposed on the first surface or the second surface.

In one embodiment, the substrate has at least one pin whereby the substrate is inserted into the main board.

In one embodiment, the wire is electrically connected to the heat generating device and the pin.

In one embodiment, the substrate is an aluminum substrate.

In one embodiment, the substrate further has at least one copper foil layer.

In one embodiment, the heat dissipating layer has at least one foot portion whereby the heat dissipating layer is inserted into the main board.

In one embodiment, the heat dissipating layer is made by metal material.

In one embodiment, the metal material includes copper, aluminum, nickel, gold, silver or their alloys.

In one embodiment, the substrate and the heat dissipating layer are connected to each other by locking, screwing, riveting, or surface mount technology (SMT).

In one embodiment, the heat dissipating device is a surface mount device (SMD).

In one embodiment, the heat dissipating layer has a plurality of fins.

In one embodiment, the heat dissipating module further comprises a heat conductive insulation layer disposed between the substrate and the heat dissipating layer.

In one embodiment, the heat conductive insulation layer is made by aluminum oxide, beryllium oxide, silicon carbide, silicon nitride or boron nitride.

As mentioned above, in the heat dissipating module according to this invention, the heat generating devices, such as chips, control units or other electronic components, which should be disposed on the main board, are disposed on the substrate (e.g. aluminum circuit board) so that the main board can spare more room for the circuit layout. More importantly, since the heat dissipating layer is connected to the substrate, the main board needn't spare much room for the disposition of the heat dissipating module and thus the utility rate of the space is increased a lot. Besides, the heat dissipating layer has the foot portion whereby the heat dissipating layer is locked to the main board, so that the heat dissipating module is firmer. And even better, since the heat dissipating layer is fixed to the main board, the area contributing to the heat dissipation effect is increased, providing a better heat dissipating effectiveness.

Furthermore, the heat dissipating module according to the invention can further include a heat conductive insulation layer. Thereby, the disposition room of the devices or circuits on the substrate is increased and the heat dissipating efficiency is also enhanced. In other words, the heat dissipating module can have a substrate of single-layout or double-layout. In comparison with the prior art, when applied to an electronic apparatus, the heat dissipating module of the invention can make the electronic apparatus have more disposition room for the devices, and can effectively enhance the heat dissipating efficiency of the electronic apparatus.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a schematic exploded diagram of a heat dissipating module according to a preferred embodiment of this invention;

FIG. 1B is a schematic perspective diagram of the heat dissipating module in FIG. 1A;

FIG. 2 is a schematic exploded diagram of anther heat dissipating module according to a preferred embodiment of the invention;

FIG. 3 is a schematic exploded diagram of anther heat dissipating module according to a preferred embodiment of the invention; and

FIG. 4 is a schematic exploded diagram of a variation of the heat dissipating module having a different heat dissipating layer according to a preferred embodiment of the invention.

### DETAILED DESCRIPTION OF THE INVENTION

The present invention will be apparent from the following detailed description, which proceeds with reference to the accompanying drawings, wherein the same references relate to the same elements.

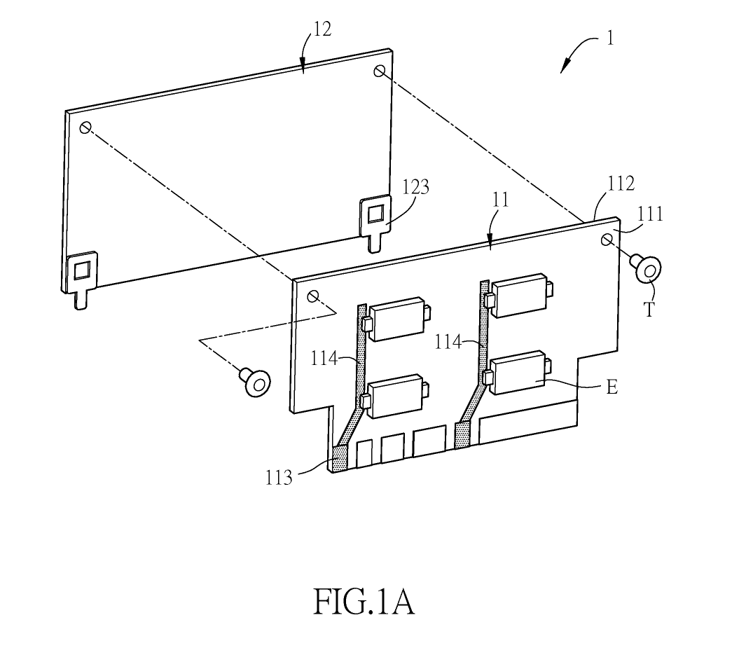

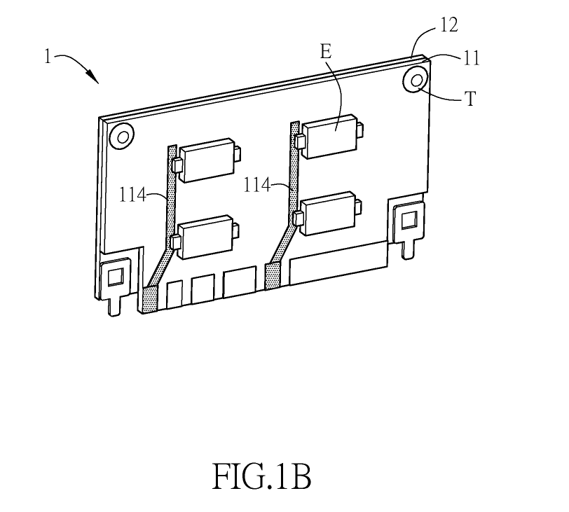

FIG. 1A is a schematic exploded diagram of a heat dissipating module according to a preferred embodiment of this invention, and FIG. 1B is a schematic perspective diagram of the heat dissipating module in FIG. 1A. As shown in FIGS. 1A and 1B, the heat dissipating module 1 includes at least one substrate 11 and a heat dissipating layer 12. The heat dissipating module 1 can be disposed on a main board (not shown) uprightly. In detail, the heat dissipating module 1 is disposed on the main board by the method of pin through hole (PTH) or surface mount technology (SMT). The main board can be a motherboard, but is not limited thereto. The above-mentioned connection method (PTH or SMT) can be understood by those skilled in the art, and therefore is not described here for conciseness. As below, the components and structure of the heat dissipating module 1 will be illustrated.

The substrate 11 is an aluminum substrate. At least one heat generating device E is electrically connected to the substrate 11, and four heat generating devices E are shown in this embodiment for example. The substrate 11 has a first surface 111 and a second surface 112, and the heat generating device E is disposed on the first surface 111 by SMT. The heat generating device E can be an active component, such as a transistor, but is not limited thereto. The heat generating device E denotes a device that will generate heat during the operation. Disposing the heat generating device E on the substrate 11 by SMT can bring some advantages of decreasing the required components, simplifying the manufacturing process and facilitating the automation.

In this embodiment, the substrate 11 is a printed circuit board (PCB), which has a circuit pattern including a plurality of wires 114 formed by etching a copper foil layer. However, the invention is not limited thereto. In a practical case, the substrate can be a module board or a package substrate for example. In detail, the first surface 111 and second surface 112 of the substrate 11 are coated each with a copper foil layer that is then etched to form the circuit pattern electrically connecting to the heat generating devices E disposed on the substrate 11. In this embodiment, since the heat generating devices E are only disposed on the first surface 111, the circuit pattern is at least disposed on the first surface 111. In other words, the wires 114 can be only disposed on the first surface 111. In other embodiments, the heat generating devices or the circuit pattern can be disposed on the opposite surfaces of the substrate 11.

The heat dissipating layer 12 is made by metal material, and here for example, is made by aluminum. However, other metals, such as the metal capable of high heat conduction, e.g. copper, aluminum, nickel, gold, silver or their alloys, can be used as the material of the heat dissipating layer 12.

In this embodiment, the heat dissipating layer 12 is an aluminum plate shaped like a rectangle, disposed on the second surface 112 of the substrate 11. In other words, the heat dissipating layer 12 and the heat dissipating devices E are disposed on the opposite surfaces of the substrate 11, respectively. The heat dissipating layer 12 is connected to the substrate 11 by rivets, but this invention is not limited thereto. Other ways, such as locking or screwing also can be used in the invention for connecting the heat dissipating layer 12 and the substrate 11.

The substrate 11 has a pin 113, which is used to fix the substrate 11 to the main board. In detail, a plurality of the pins 113 are made on the substrate 11, a plurality of positioned holes are correspondingly made on the main board, and thus the pins 113 can pass through the positioned holes for fixing the substrate 11 to the main board. Furthermore, a solder paste can be used to further connect the substrate 11 and the main board. In this embodiment, the pins 113 of the substrate 11 are electrically connected to the heat generating devices E through the wires 114. The pins 113 also can have a circuit layout. Through the connection between the pins 113 and the main board, the substrate 11 and the heat generating devices E can be electrically connected to the main board. The heat dissipating layer 12 has a foot portion 123 whereby the heat dissipating layer 12 can be fixed to the main board. Likewise, a plurality of positioned holes are correspondingly made on the main board for accommodating the foot portion 123 of the heat dissipating layer 12. By both of that the substrate 11 is connected to the heat dissipating layer 12 and that the pins 113 of the substrate 11 and the foot portion 123 of the heat dissipating layer 12 are connected to the main board, the connection stability and strength between the heat dissipating module 1 and the main board are enhanced.

Heat dissipating layer 12 is an aluminum plate with the size and shape both similar to the substrate 11. In this embodiment, since the pins 113 of the substrate 11 are configured with the functions of the firmness with the main board and the connection with the wire, the portion of the pins 113 of the substrate 11 is slightly larger than the corresponding portion of the heat dissipating layer 12, and the whole substrate 11 is also slightly larger than the heat dissipating layer 12. However, this invention is not limited thereto.

Besides, because the heat dissipating layer 12 and the substrate 11 are respectively configured with the foot portion 123 and the pins 113, they can be fixed to the main board independently. Thereby, the substrate 11 and the heat dissipating layer 12 can be replaced by the ones of different size or shape, according to the various applied electronic apparatuses. That is, the heat dissipating module of this invention has adjustable components, thereby helping the reduction of the assembly cost and the facilitation of the manufacturing process.

Through the all above-mentioned configuration, the substrate 11 is capable of carrying the heat generating devices E and conducting the heat generated by the heat generating devices E to the heat dissipating layer 12 that is connected to the substrate 11. Furthermore, in this embodiment, since the substrate 11 and the heat dissipating layer 12 are similar to each other in size and each shaped like a rectangle, they have a larger area than the heat generating devices E disposed on the substrate 11. Therefore, they can evenly dissipate the heat generated by the heat generating devices E.

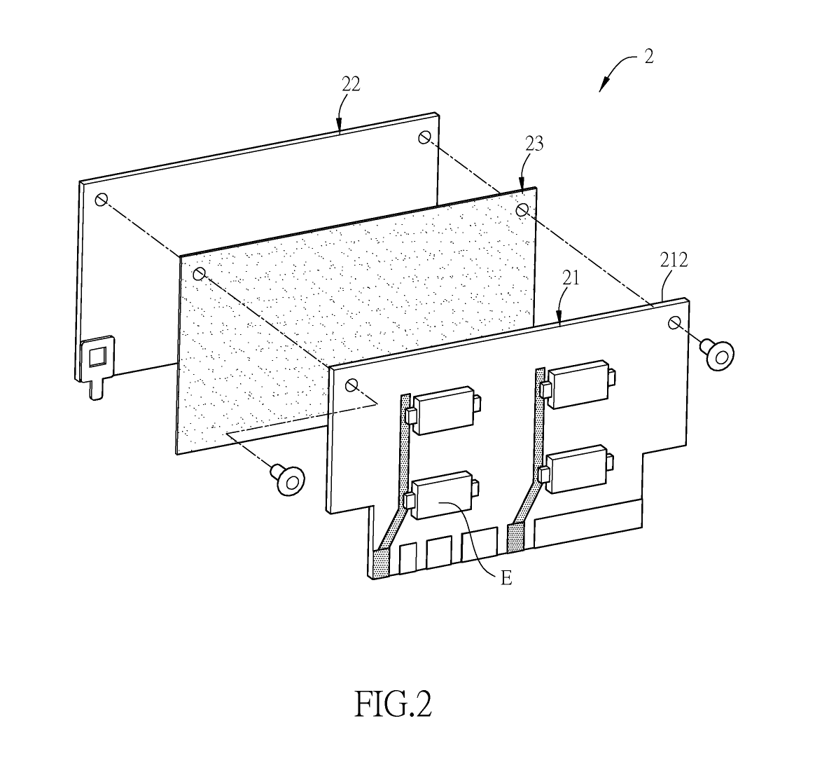

FIG. 2 is a schematic exploded diagram of anther heat dissipating module according to a preferred embodiment of the invention. As shown in FIG. 2, the heat dissipating module 2 of this embodiment has similar structure and technical features with the above embodiment, but differently, it further includes a heat conductive insulation layer 23. The heat conductive insulation layer 23 is disposed between the substrate 21 and the heat dissipating layer 22, and is made by aluminum oxide for example. By such configuration, the second surface 212 of the substrate 21 contacting the heat conductive insulation layer 23 can be configured with at least one heat generating device E or a circuit layout, so that the number of the heat generating devices E of the whole heat dissipating module 2 is increased. Besides the insulation property, the heat conductive insulation layer 23 also has high thermal conductivity, and thus can improve the heat dissipation efficiency on the heat generating devices E. The heat conductive insulation layer 23 can be made by other material of high thermal conductivity, such as beryllium oxide, silicon carbide, silicon nitride or boron nitride. However, the invention is not limited thereto.

To be noted, when the opposite surfaces of the substrate 21 of the heat dissipating module 2 are both configured with the heat generating devices E, the heat conductive insulation layer 23 needs to have the same size as the substrate 21 for achieving the complete heat conduction and insulation.

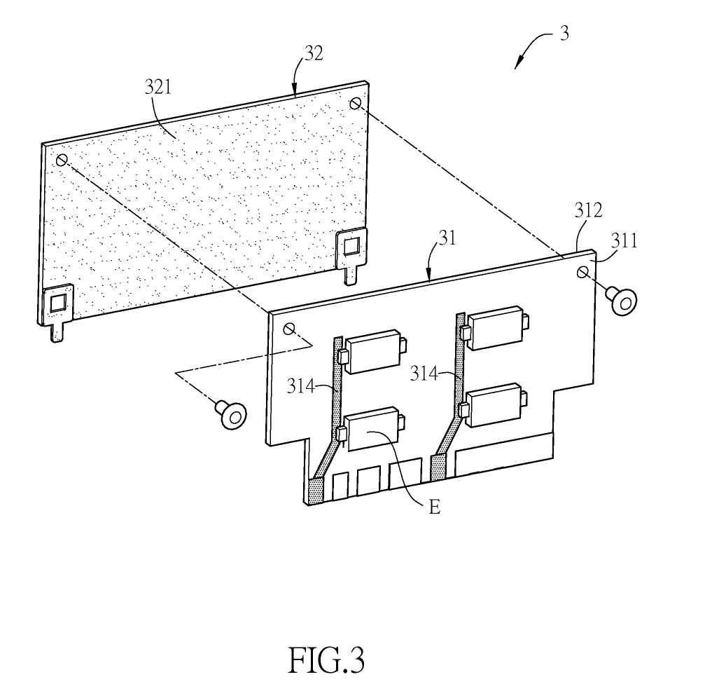

FIG. 3 is a schematic exploded diagram of anther heat dissipating module according to a preferred embodiment of the invention. As shown in FIG. 3, the heat dissipating module 3 of this embodiment has similar structure and technical features with the heat dissipating module 1, but differently, a first surface 321 of the heat dissipating layer 32 is configured with an insulation effect. In this embodiment, the first surface 321 of the heat dissipating layer 32 is covered by a ceramic material, and has properties of high thermal conductivity and insulation. So, like the above-mentioned heat dissipating module 2, the first surface 311 and second surface 312 of the substrate 31 can be both configured with the heat generating devices E or wires 314. Thereby, the manufacturing process can be facilitated and the heat dissipation efficiency can be enhanced, and even better, the size of the heat dissipating module can be decreased. Furthermore, because the thermal expansion coefficient and high heat-resistant capability of the ceramic material approximate those of the semiconductor material, this invention can solve the problems of thermal strain and high temperature process in a practical application. To be noted, in this embodiment, the insulation effect can be provided by many ways or materials. For example, the first surface 321 of the heat dissipating layer 32 is coated with an appropriate material so as to achieve both of the insulation and heat dissipation. However, this invention is not limited thereto.

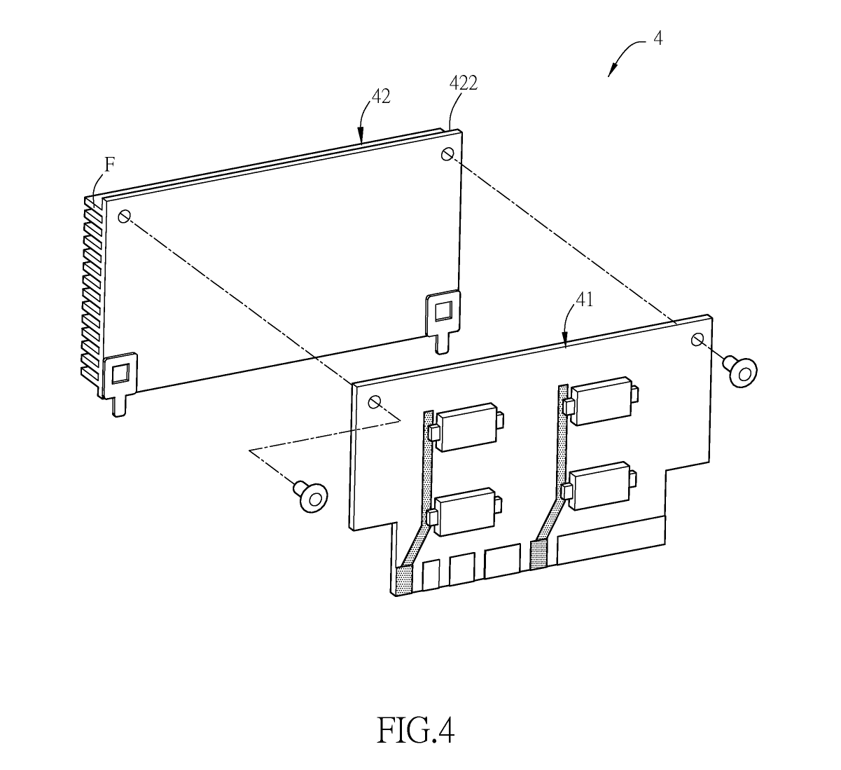

FIG. 4 is a schematic exploded diagram of anther heat dissipating module having a different heat dissipating layer according to a preferred embodiment of the invention. As shown in FIG. 4, the heat dissipating module 4 of this embodiment has similar structure and technical features with the heat dissipating module 1, but differently, the heat dissipating layer 42 further includes a plurality of heat dissipating fins F to provide a further heat dissipating effect. The heat dissipating fins F are disposed on the second surface 422 of the heat dissipating layer 42 away from the substrate 41. The heat dissipating fins F are separated from each other in parallel on the heat dissipating layer 42. The number, size and arrangement of the heat dissipating fins F are not limited herein. For example, the heat dissipating fins F can be separated from each other inclinedly or perpendicularly, according to the structure of the applied electronic apparatus, configuration of other heat dissipating components and entire heat dissipating requirement.

In this embodiment, the heat dissipating fins F and the heat dissipating layer 42 are integrally formed. In other embodiments, the heat dissipating fins F can be connected to the heat dissipating layer 42 by embedding, locking, fastening or adhering, for example.

To be noted, the heat dissipating module of this invention can further include other heat dissipating devices, such as a fan, for enhancing the whole heat dissipation effectiveness. In a practical application, it can be designed according to the structure of the applied electronic apparatus, configuration of other heat dissipating components and entire heat dissipating requirement.

In summary, in the heat dissipating module according to this invention, the heat generating devices, such as chips, control units or other electronic components, which should be disposed on the main board, are disposed on the substrate (e.g. aluminum circuit board) so that the main board can spare more room for the circuit layout. More importantly, since the heat dissipating layer is connected to the substrate, the main board needn't spare much room for the configuration of the heat dissipating module and thus the utility rate of the space is increased a lot. Besides, the heat dissipating layer has the foot portion whereby the heat dissipating layer is locked to the main board, so that the heat dissipating module is firmer. And even better, since the heat dissipating layer is fixed to the main board, the area contributing to the heat dissipation effect is increased, providing a better heat dissipating effectiveness.

Furthermore, the heat dissipating module according to the invention can further include a heat conductive insulation layer. Thereby, the disposition room of the devices or circuits on the substrate is increased and the heat dissipating efficiency is also enhanced. In other words, the heat dissipating module can have a substrate of single-layout or double-layout. In comparison with the prior art, when applied to an electronic apparatus, the heat dissipating module of the invention can make the electronic apparatus have more disposition room for the devices, and can effectively enhance the heat dissipating efficiency of the electronic apparatus.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A heat dissipating module, comprising:
at least one substrate having a first surface and a second surface; and
a heat dissipating layer disposed on the second surface,
wherein at least one heat generating device is electrically connected to the first surface, and the heat dissipating module is disposed on a main board uprightly.

2. The heat dissipating module as recited in claim 1, further comprising:
at least one wire disposed on the first surface or the second surface.

3. The heat dissipating module as recited in claim 2, wherein the substrate has at least one pin whereby the substrate is inserted into the main board.

4. The heat dissipating module as recited in claim 3, wherein the wire is electrically connected to the heat generating device and the pin.

5. The heat dissipating module as recited in claim 1, wherein the substrate is an aluminum substrate.

6. The heat dissipating module as recited in claim 1, wherein the substrate further has at least one copper foil layer.

7. The heat dissipating module as recited in claim 1, wherein the heat dissipating layer has at least one foot portion whereby the heat dissipating layer is inserted into the main board.

8. The heat dissipating module as recited in claim 1, wherein the heat dissipating layer is made by metal material.

9. The heat dissipating module as recited in claim 8, wherein the metal material includes copper, aluminum, nickel, gold, silver or their alloys.

10. The heat dissipating module as recited in claim 1, wherein the substrate and the heat dissipating layer are connected to each other by locking, screwing, riveting, or surface mount technology (SMT).

11. The heat dissipating module as recited in claim 1, wherein the heat dissipating device is a surface mount device (SMD).

12. The heat dissipating module as recited in claim 1, wherein the heat dissipating layer has a plurality of fins.

13. The heat dissipating module as recited in claim 1, further comprising:
a heat conductive insulation layer disposed between the substrate and the heat dissipating layer.

14. The heat dissipating module as recited in claim 13, wherein the heat conductive insulation layer is made by aluminum oxide, beryllium oxide, silicon carbide, silicon nitride or boron nitride.
